(19) United States
(12) Patent Application Publication
(10) Pub. No.: US 2009/0316361 A1
(43) Pub. Date: Dec. 24, 2009

(54) Method and apparatus for controlling the output of solar arrays

(76) Inventor: Daniel Simon, Chicago, IL (US)

Correspondence Address: Daniel Simon, Apt.#1003, 5555 N. Sheridan Road, Chicago, IL, 60640, US

(21) Appl. No.: 12/214,831

(22) Filed: Jun. 23, 2008

(51) Int. Cl. H05K 7/20

(52) U.S. Cl. 361/699

(57) ABSTRACT

A method to control the temperature of a circulating fluid and thereby control the electrical output of a PV array is provided along with an apparatus for doing so which adds simple mechanical, data measurement and control elements to prior art systems. Given a set amount of sunlight, electrical output from a solar PV array will change if the temperature of the array changes. One can change the temperature of a PV array by circulating a fluid through a loop in thermal contact with the array. Controlling the temperature of this circulating fluid, allows one to control the electrical output from the array.

### BACKGROUND

1. Field of the Invention

The present invention relates generally to the field of controlling photovoltaic solar arrays and more particularly to the control of the temperature of a working fluid circulating through a photovoltaic solar array to enhance control of the power output from the array.

2. Description of the Prior Art

There is growing interest worldwide in reliable and predictable low carbon energy sources such as solar photovoltaic (PV), as the cost of solar power falls relative to fossil generated power. Worldwide PV capacity has recently expanded enough that PV solar arrays in the tens of megawatts in size exist, and larger PV solar arrays are being proposed (i.e. utility scale PV plants). Despite the increased interest and decreased cost, many utilities have been slow to adopt or invest in solar PV arrays for power generation. One complaint frequently cited by utilities is “intermittency of sunlight” or a lack of control over output levels for PV arrays relative to fossil generating technologies. Utilities are used to generating more or less power to meet demand. Simply stated a PV array's power output is primarily dependant on sunlight levels which are hard to predict, let alone control, for any given instant. For such utilities a PV array would provide greater value if they could control its output.

It is a well established fact that solar PV panels (especially silicon based technologies) suffer from reduced electrical output as their operating temperature increases. It is also common for PV panels to be located in areas with lots of sunlight such that PV panels tend to operate at elevated temperatures. This loss of output can be reversed by lowering the PV panel operating temperature. The prior art teaches numerous methods and arrangements for circulating a working fluid through panels and arrays to reduce the temperature at which they operate, thereby increasing the output from the panels in proportion to the temperature reduction. Frequently this circulating fluid is contained in a loop which may have a reservoir for storing additional working fluid. Many times the heat removed from the PV panel by the working fluid is then used for some additional purpose.

In U.S. Pat. No. 2,946,945 Regnier et al. teach of a method to improve output from PV solar cells, by circulating a fluid in thermal contact with the PV cells such that the fluid lowers the PV cells operating temperature enabling an increased PV output compared to the output if the fluid were not present. Regnier et al. envisioned using the heat removed from the PV cells by the circulating fluid to heat a battery, improving both the battery's performance and the PV cells' performance. In U.S. Pat. No. 3,976,508 Mlavsky teaches the use of a tubular solar cell device which may be used with a concentrator and cooled by a fluid circulating inside the tubular cells, and using this heated fluid in turn to provide hot water. There are numerous additional examples of prior art PV panels with and without concentration accessories designed to use a fluid in thermal contact with PV solar cells to both improve the performance of the cells (i.e. increase output by cooling the cells) and utilize the resulting heat removed by the working fluid.

Unfortunately few such “hybrid” systems have been widely adopted despite the well understood benefits. Perhaps this is because the greater complexity, design, material, and operating costs of maintaining both a PV electrical system and a circulating fluid system exceed the limited extra output generated by such a hybrid system.

It would be advantageous to have a method and apparatus that provides the user greater control of a PV solar array's output, especially if the user were a utility. The flexibility that greater control over the PV array's output might increase the value of PV within the context of managing multiple power generating assets. This would enable much wider use and benefit from our most abundant energy source, the sun.

### SUMMARY OF THE INVENTION

The present invention relates to a method and apparatus for controlling the power output of a PV solar array. Given a fixed amount of sunlight, one can increase (or decrease) the output from a PV array, panel, or cell by decreasing (or increasing) the operating temperature of the PV array, panel, or cell, via a working fluid in thermal contact with the array, panel, or cell. One can control the operating temperature of a working fluid by adding a cold temperature fluid reservoir (and a hot temperature fluid reservoir) and a heat exchanger or controllable mixing valve, to regulate the working fluid temperature, such that a desired PV array operating temperature is achieved.

If the amount of sunlight reaching a prior art PV array fluctuates, then the output of the PV array varies in proportion. But if one controls the PV array's operating temperature, via the control of the working fluid temperature, one can control the output from the solar PV array to offset the variations in sunlight levels. Thus one can produce a consistent PV output given some variation in light levels by modifying the PV array's operating temperature. Since the operator can select the appropriate working fluid, as well as the hot and cold reservoir temperatures, in principle this setup enables substantial control over the output of the PV array.

It is an object of the present invention to provide control over the output of a PV array.

It is another object of the present invention to measure and control the temperature of a working fluid, which is then used to control the temperature of a PV array.

Finally it is another object of the present invention to increase the range of temperatures over which one may control the temperature of a PV array.

By adding a cold temperature reservoir and a heat exchanger, or controllable mixing valve, to a system that had a single circulating loop with a fluid at a relatively fixed temperature, one is able to modify (primarily decrease) the operating temperature of the PV array from what it would have otherwise been, boosting the amount of power the PV array can produce at any given light level. And by adding a hot temperature reservoir and a heat exchanger, or controllable mixing valve, one is further able to modify (primarily increase) the operating temperature of the PV array from what it would have otherwise been, reducing the amount of power the PV array can produce at any given light level.

Intentionally increasing the operating temperature of a PV array (and thus reducing the power output from the array) goes against common sense in the field of solar PV devices, but doing so can be advantageous for two reasons. First this increases the temperature range over which one can control a PV array's output, which grants one control of a greater fraction of the total output. Secondly, it allows an operator, such as a utility, to manage the PV array output in a way that maximizes the value of all its generating assets in combination, rather than just adding a PV array's output (whatever it might be) on top of its existing generating profile.

### DESCRIPTION OF THE FIGURES

Attention is drawn to the following illustrations presented to aid in understanding the present invention.

FIG. 1 shows a schematic view of a prior art PV array with a circulating fluid loop.

FIG. 1A shows a plan view of the upper right corner of a prior art PV array with a circulating fluid loop, showing the fluid loop—dashed lines—behind a PV panel.

FIG. 1B shows a side view of a panel in a prior art PV array with a circulating fluid loop, showing the fluid loop in thermal contact with and under PV material in the panel.

FIG. 1C shows a plan view of the upper right corner of a prior art PV array built with concentrating optics and with a circulating fluid loop, showing the fluid loop—dashed lines—behind a PV panel.

FIG. 2 shows a schematic view of an embodiment of the present invention showing a computer for automatic control, a circulating fluid loop with a fluid reservoir, a cold temperature fluid reservoir, a heat transfer device, a PV array, a second heat transfer device, and multiple temperature sensors.

FIG. 2A shows a cut away view of a heat transfer device used to control the circulating fluid loop temperature, namely a heat exchanger.

FIG. 3 shows a schematic view of the preferred embodiment of the present invention showing a computer for automatic control, a circulating fluid loop with a fluid reservoir, a cold temperature fluid reservoir, a hot temperature fluid reservoir, a heat transfer device, a PV array, a second heat transfer device, and multiple temperature sensors.

FIG. 3A shows a cut away view of a heat transfer device used to control the circulating fluid loop temperature, namely an adjustable valve that allows the fluid from different reservoirs to mix directly.

Several drawings and illustrations have been presented to better explain the construction and functioning of embodiments of the present invention. The scope of the present invention is not limited to what is shown in the figures.

### DESCRIPTION OF THE INVENTION

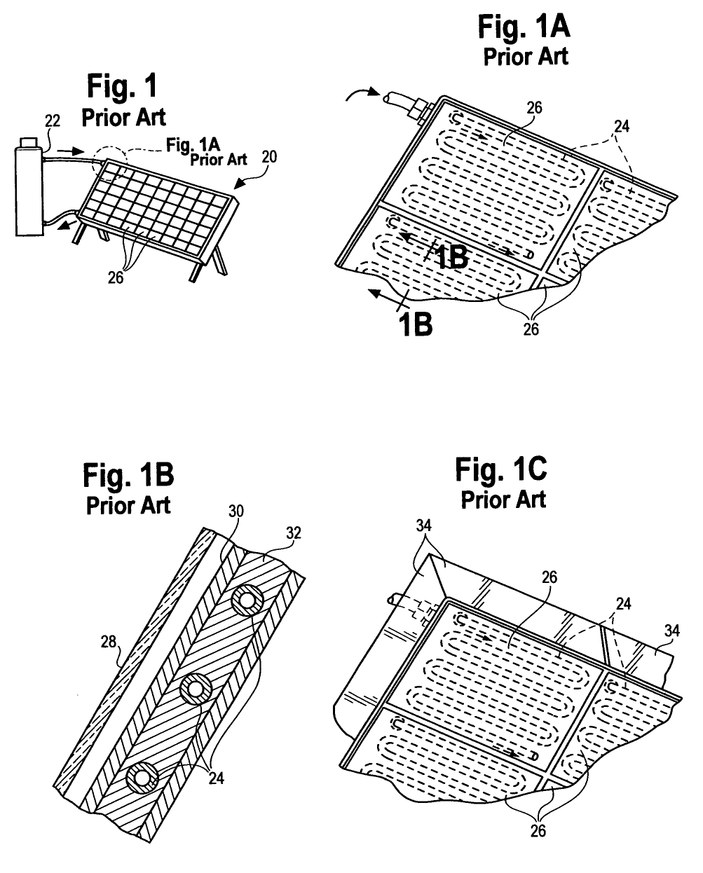

FIG. 1 and FIG. 1A show a prior art photovoltaic (PV) array with a circulating fluid loop. This is often called a hybrid solar array because it produces both electrical energy and thermal energy (in the form of a fluid heated by the array). A hybrid solar array 20 consists of an array of PV panels 26, a fluid reservoir 22, a circulating fluid (not shown) and a circulating fluid conduit 24 in thermal contact with the PV panels 26. FIG. 1B shows how an individual panel in the array might be constructed. A transparent panel cover 28 is located above a PV material 30 which in turn is located above a thermal contact medium 32 which is in thermal contact with both the PV material 30 and the circulating fluid conduit 24. FIG. 1C shows one way in which a concentrating optics 34, in this case reflectors, may be used to increase the amount of sunlight reaching PV material 30. These figures are intended to simply show the principle elements present in prior art hybrid solar arrays, there are numerous additional ways to construct hybrid solar arrays.

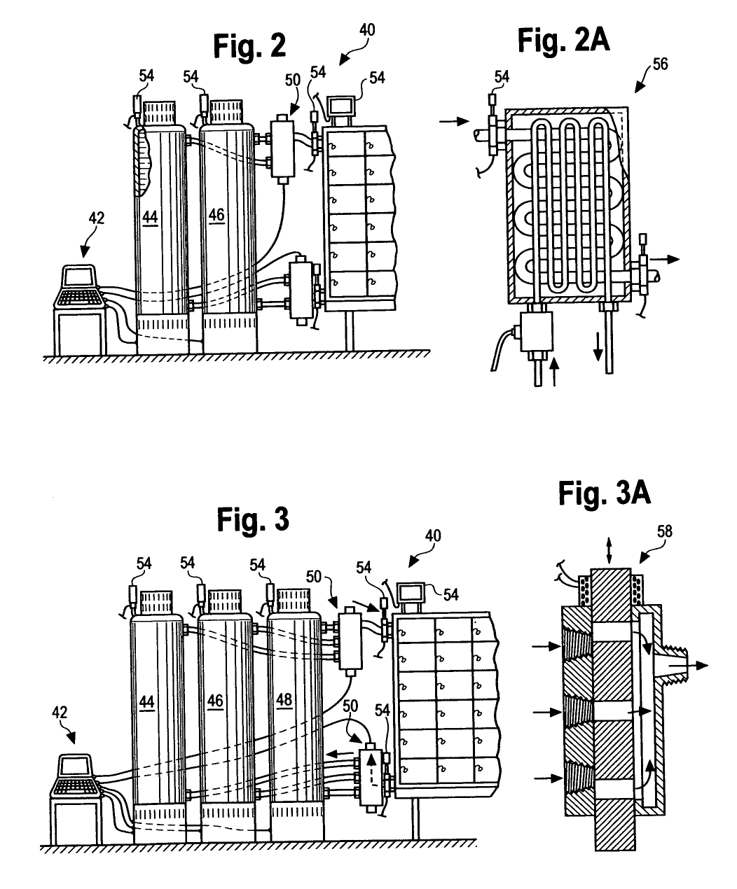

FIG. 2 shows a schematic view of the preferred embodiment of the present invention, which may be called a dynamic solar array 40. From left to right the principle elements of the invention are a controller 42, a first fluid reservoir 44 containing fluid at a first temperature, a second fluid reservoir 46 containing fluid at a second temperature, a first heat transfer device 50 (upper unit), which delivers a fluid at some intermediate temperature to a circulating fluid loop, in thermal contact with PV array 26. Heat transfer device 50 can be any device for regulating the temperature of two fluid streams, such as a heat exchanger or fluid mixing valve. The circulating fluid loop while not explicitly labeled in FIG. 2, consists of circulating fluid conduit 24 as was shown in the prior art FIG. 1A, FIG. 1B, & FIG. 1C. FIG. 2 also shows multiple temperature sensors 52, and a light level sensor 54 that provide feedback/data to controller 42. Finally FIG. 2 shows a second heat transfer device 50 (lower unit) which may be used to recover heat gained by the fluid in traversing PV array 26, or otherwise condition the fluid to be returned to either first fluid reservoir 44 or second fluid reservoir 46.

FIG. 2A shows an embodiment of heat transfer device 50, which is essentially a heat exchanger 56. When controller 42 is able to control both the fluid flow rates, and measure via temperature sensors 52, (or calculate) the input and output temperature of each fluid, heat exchanger 56 can deliver fluid at a desired temperature between the first fluid temperature and the second fluid temperature.

FIG. 3 shows a schematic view of an alternate embodiment of the present invention, which may be called a dynamic solar array 40. From left to right the principle elements of the invention are a controller 42, a first fluid reservoir 44 containing fluid at a first temperature, a second fluid reservoir 46 containing fluid at a second temperature, a third fluid reservoir 48 containing fluid at a third temperature, a first heat transfer device 50 (upper unit), which delivers a fluid at some intermediate temperature to a circulating fluid loop, in thermal contact with PV array 26. Heat transfer device 50 can be any device for regulating the temperature of up to three fluid streams, such as a heat exchanger or fluid mixing valve. The circulating fluid loop is (again) not explicitly labeled in FIG. 3, but consists of circulating fluid conduit 24 as was shown in the prior art FIG. 1A, FIG. 1B, & FIG. 1C. FIG. 3 also shows multiple temperature sensors 52, and a light level sensor 54 that provide feedback/data to controller 42. Finally FIG. 3 shows a second heat transfer device 50 (lower unit) which may be used to recover heat gained by the fluid in traversing PV array 26, or otherwise condition the fluid to be returned to either first fluid reservoir 44, or second fluid reservoir 46, or third fluid reservoir 48.

FIG. 3A shows an embodiment of heat transfer device 50, which is essentially a fluid mixing valve 58. When controller 42 is able to control the three fluid flow rates, and measure via temperature sensor(s) 52, or calculate, the input and output temperature of each fluid, fluid mixing valve 58 can deliver fluid at a desired temperature between the highest and lowest fluid temperatures.

### Operation of the Invention

The purpose of this invention is to increase the control that a solar array owner or operator has over the output of a solar array. Although one may not always be able to control how much sunlight a PV array receives, one can control the temperature of the PV array which allows one to change the output. The degree of control will be limited by the temperature difference between the two fluid reservoirs (or the range of hottest and coldest fluid temperature if three reservoirs are used) so one will want a wide temperature range. A PV array operator can increase, decrease or hold steady the PV array output.

Assuming a steady amount of sunlight falls on the preferred embodiment of this invention, and further assuming controller 42 is circulating the fluid through PV array 26 at a temperature (T.sub.m), in the middle of the available temperature range (T.sub.high-T.sub.low), equal amounts of fluid enter heat transfer device 50 (upper unit) from first fluid reservoir 44 and from second fluid reservoir 46 which by assumption is at the lower temperature (T.sub.low).

If the operator wants to increase the output from PV array 26, the operator can set controller 42 to lower the temperature of the circulating fluid. Controller 42 lowers the circulating fluid temperature by increasing the flow of fluid to heat transfer device 50 from second fluid reservoir 46 and/or decreasing the flow of fluid from first fluid reservoir 44, until the desired circulating fluid temperature (T.sub.d) is achieved, so long as the desired fluid temperature (T.sub.d) is greater than or equal to the second fluid temperature (T.sub.low). In this scenario, multiple temperature sensors 52 provide fluid temperature feedback to controller 42 to help the circulating fluid reach and maintain the desired temperature (T.sub.d).

If the operator wants to decrease the output from PV array 26, the operator can set controller 42 to raise the temperature of the circulating fluid. Controller 42 raises the circulating fluid temperature by decreasing the flow of fluid to heat transfer device 50 (upper unit) from second fluid reservoir 46 and/or increasing the flow of fluid from first fluid reservoir 44, until the desired circulating fluid temperature (T.sub.d) is achieved, so long as the desired fluid temperature (T.sub.d) is less than or equal to the first fluid temperature (T.sub.high). Again multiple temperature sensors 52 provide fluid temperature feedback to controller 42 to help the circulating fluid reach and maintain the desired temperature (T.sub.d).

Finally we consider sunlight levels that are not steady, but an operator who wishes to generate a consistent amount of power. If light levels decrease which may be measured with light level sensor 54, the operator can increase output by setting controller 42 to lower the temperature of the circulating fluid, as described above. And if light levels later increase, the operator can decrease output by setting controller 42 to raise the temperature of the circulating fluid, as is described above.

An alternative embodiment of the invention with third fluid reservoir 48 containing fluid assumed to be at a higher temperature than first fluid reservoir 44 works much the same way, but with three possible fluid flows to heat transfer device 50 for controller 42 to manage, along with a greater range of temperatures that the circulating fluid can achieve.

In an alternate embodiment, heat transfer device 50 can be constructed from a series of two standard double-flow valves, where the first standard double-flow valve combines two of the fluid flows, and the second standard double-flow valve combines the third fluid flow with this combined fluid flow.

In any embodiment of this invention the fluid exiting PV array 26 may be at a higher temperature than when it entered PV array 26. The second heat transfer device 50 (lower unit) can be used to extract this extra heat for some additional purpose, or use the extra heat to condition the circulating fluid for return to one or more fluid reservoirs.

For any given PV technology it is simple to calculate (or measure) the amount of electrical output change produced by a fixed change in circulating fluid temperature, allowing one to model and predict the amount of control a dynamic solar array will produce. Conversely one can calculate the type of dynamic solar array inputs, reservoir temperatures, flow rates and PV material necessary to produce a given level of output control.

Several descriptions and illustrations have been presented to aid in understanding the structure and functioning of the present invention. One skilled in the art will realize that numerous changes and variations are possible without departing from the spirit of the invention. Each of these changes and variations is within the scope of the present invention.

1. An apparatus for controlling the electrical output of a photovoltaic array comprising:
a plurality of photovoltaic panels;
a thermally insulated circulating fluid loop, containing a circulating fluid, in thermal contact with said plurality of photovoltaic panels;
a first fluid reservoir containing fluid at a first temperature;
a second fluid reservoir containing fluid at a second temperature below said first temperature;
a heat transfer device to transfer heat from said fluid at a first temperature and said fluid at a second temperature to achieve an intermediate temperature for said circulating fluid; and,
a controller capable of adjusting said heat transfer device such that said intermediate temperature can be any temperature between said first temperature and said second temperature, inclusive, wherein said intermediate temperature is selected by said controller to increase, decrease, or hold steady the electrical output from said plurality of photovoltaic panels.

2. The apparatus for controlling the electrical output of a photovoltaic array of claim 1 wherein said controller is a computer.

3. The apparatus for controlling the electrical output of a photovoltaic array of claim 1 further comprising a plurality of temperature sensors located at various points along said circulating fluid loop to provide feedback to said controller.

4. The apparatus for controlling the electrical output of a photovoltaic array of claim 1 wherein said heat transfer device is a heat exchanger.

5. The apparatus for controlling the electrical output of a photovoltaic array of claim 4 further comprising a second heat exchanger for recovering heat from said circulating fluid after traversing said photovoltaic array.

6. The apparatus for controlling the electrical output of a photovoltaic array of claim 1 wherein said circulating fluid, said fluid at a first temperature, and said fluid at a second temperature, are all water.

7. The apparatus for controlling the electrical output of a photovoltaic array of claim 1 wherein said heat transfer device is a valve for mixing fluids.

8. The apparatus for controlling the electrical output of a photovoltaic array of claim 7 further comprising a heat exchanger for recovering or reusing heat from said circulating fluid after traversing said photovoltaic array.

9. The apparatus for controlling the electrical output of a photovoltaic array of claim 1 further comprising at least one light level sensor located in close proximity to at least one of said photovoltaic panels to provide feedback on ambient light levels to said controller.

10. The apparatus for controlling the electrical output of a photovoltaic array of claim 1 wherein said plurality of photovoltaic panels contain light concentrating elements such as lenses or mirrors.

11. An apparatus for controlling the electrical output of a photovoltaic array comprising:
a plurality of photovoltaic panels;
a thermally insulated circulating fluid loop, containing a circulating fluid, in thermal contact with said plurality of photovoltaic panels;
a first fluid reservoir containing fluid at a first temperature;
a second fluid reservoir containing fluid at a second temperature below said first temperature;
a third fluid reservoir containing fluid at a third temperature above said first temperature;
a heat transfer device to transfer heat from said fluid at a first temperature, and said fluid at a second temperature or said fluid at a third temperature to achieve an intermediate temperature for said circulating fluid; and,
a controller capable of adjusting said heat transfer device such that said intermediate temperature can be any temperature between said second temperature and said third temperature, inclusive, wherein said intermediate temperature is selected by said controller to increase, decrease, or hold steady the electrical output from said plurality of photovoltaic panels.

12. The apparatus for controlling the electrical output of a photovoltaic array of claim 11 wherein said controller is a computer.

13. The apparatus for controlling the electrical output of a photovoltaic array of claim 11 further comprising a plurality of temperature sensors located at various points along said circulating fluid loop to provide feedback to said controller.

14. The apparatus for controlling the electrical output of a photovoltaic array of claim 11 wherein said heat transfer device is a heat exchanger.

15. The apparatus for controlling the electrical output of a photovoltaic array of claim 14 further comprising a second heat exchanger for recovering heat from said circulating fluid after traversing said photovoltaic array.

16. The apparatus for controlling the electrical output of a photovoltaic array of claim 11 wherein said heat transfer device is a valve for mixing fluids.

17. The apparatus for controlling the electrical output of a photovoltaic array of claim 16 further comprising a heat exchanger for recovering or reusing heat from said circulating fluid after traversing said photovoltaic array.

18. The apparatus for controlling the electrical output of a photovoltaic array of claim 11 wherein said plurality of photovoltaic panels contain light concentrating elements such as lenses or mirrors.

19. A method for controlling the output of a photovoltaic array comprising the steps of:
placing a thermally insulated circulating fluid loop, containing a circulating fluid in thermal contact with a plurality of photovoltaic panels;
maintaining at least two fluid reservoirs each at different temperatures;
attaching a heat transfer device between said fluid reservoirs and said plurality of photovoltaic panels to achieve an intermediate temperature for said circulating fluid;
using a controller to adjust said heat transfer device to achieve a desired temperature for said circulating fluid between said different temperatures, wherein said controller selects said desired temperature to increase, decrease, or hold steady the electrical output from said plurality of photovoltaic panels.

20. The method of claim 19 further comprising the step of attaching a plurality of temperature sensors before and after said heat transfer device to provide feedback to said controller.
